(19) United States
(12) Patent Application Publication
(10) Pub. No.: US 2026/0006908 A1
(43) Pub. Date: Jan. 1, 2026

(54) L-SHAPED STACKED FIELD EFFECT TRANSISTOR ISOLATED WITH TOP AND BOTTOM GATES

(71) Applicant: International Business Machines Corporation, Armonk, NY (US)

(72) Inventors: Chen Zhang, Santa Clara, CA (US); Shahrukh Khan, Sandy Hook, CT (US); Ruilong Xie, Niskayuna, NY (US); Shay Reboh, Guilderland, NY (US)

(21) Appl. No.: 18/755,279

(22) Filed: Jun. 26, 2024

(51) Int. Cl. H01L 27/092; H01L 21/822; H01L 21/8238; H01L 29/06; H01L 29/423; H01L 29/66; H01L 29/775; H01L 29/786

(52) U.S. Cl. CPC H10D 84/856; H10D 30/014; H10D 30/43; H10D 30/6735; H10D 30/6757; H10D 62/121; H10D 64/017; H10D 84/0167; H10D 84/017; H10D 84/0188; H10D 84/038; H10D 88/01

(57) ABSTRACT

A semiconductor has a gate line with a gate line opening flanked by a pair of source/drains. In the gate line opening are a bottom transistor and a top transistor. The bottom transistor includes a bottom set of nanosheets wrapped by a bottom workfunction material while the top transistor includes a top set of nanosheets wrapped by a top workfunction material. A dielectric structure separates the bottom transistor and the top transistor. The dielectric structure includes a middle dielectric portion (which can be L-shaped), a first plug laterally contacting a first side of the middle dielectric portion and a second plug laterally contacting a second side of the middle dielectric portion.

### BACKGROUND

The present invention relates generally to the electrical, electronic and computer arts and, more particularly, to techniques for forming co-present independent gate contacts in the same gate line of a complementary field effect transistors (CFETs) and the like.

Traditional gate-all-around FETs stack several p-type wires on top of each other. In a separate device, the transistor stacks n-type wires on each other. However, with continued scaling a need to reduce cell active area footprint exists.

### BRIEF SUMMARY

Principles of the invention provide techniques for a placeholder with dielectric liner protection to prevent direct backside contacts (DBC) from shorting to gate. In one aspect, an exemplary semiconductor structure includes a gate line with a gate line opening flanked by a pair of source/drains. In the gate line opening are a bottom transistor and a top transistor. The bottom transistor includes a bottom set of nanosheets wrapped by a bottom workfunction material while the top transistor includes a top set of nanosheets wrapped by a top workfunction material. A dielectric structure separates the bottom transistor and the top transistor. The dielectric structure includes a middle dielectric portion (which can be L-shaped), a first plug laterally contacting a first side of the middle dielectric portion and a second plug laterally contacting a second side of the middle dielectric portion. The dielectric structure forms an isolation structure between the top and bottom gates to allow separate control of stacked transistors thereby improving scaling in sequential logic.

In another aspect, another exemplary stacked complementary field effect transistor (CFET) includes a top set of nanosheets surrounded by a top workfunction material, a bottom set of nanosheets surrounded by a bottom workfunction material in which the top set of nanosheets is over the bottom set of nanosheets. The stacked CFET also includes a dielectric structure separating the top set of nanosheets from the bottom set of nanosheets. The dielectric structure includes a stepped middle dielectric portion laterally flanked by a first plug on a first side, and a stepped second plug on a second side. The dielectric structure forms an isolation structure between the top and bottom gates to allow separate control of stacked transistors thereby improving scaling in sequential logic.

In still a further aspect, an exemplary method of forming a semiconductor structure includes forming an alternating stack of nanosheets and sacrificial material on a substrate, the alternating stack having a top stack, a bottom stack and a middle sacrificial layer vertically between the top stack and the bottom stack and then patterning the alternating stack to form an active area having a stepped profile flanked by isolation regions, thereby forming a patterned alternating stack. A dummy layer and a gate level dielectric are formed on the substrate and patterned to form a gate line. Next the middle sacrificial layer is replaced from the patterned alternating stack with a middle dielectric portion and the patterned alternating stack on either side of the gate line is etched to expose sidewalls of the nanosheets and the sacrificial material. The exposed sidewalls of the sacrificial material are etched to form recesses in which inner spacers are placed. From the exposed sidewalls of the nanosheets source/drains are grown. Next an opening over the gate line is made to expose the dummy layer which is subsequently removed to expose a top and sidewalls of the patterned alternating stack in the gate line. This allows removal of the sacrificial material from the patterned alternating stack. Now a bottom gate material can be formed around the nanosheets and middle dielectric portion in the gate line. The bottom gate material is recessed to expose the top stack and a part of the middle dielectric portion. A first plug and a second plug are formed on either side of the middle dielectric portion. A top gate material is formed on the first plug, the second plug, the middle dielectric portion and the top stack. The method creates self-aligned plugs of a dielectric structure which isolates top and bottom gates to allow separate control of stacked transistors thereby improving scaling in sequential logic.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
Allow further scaling, by stacking both nFET and pFET nanosheets on each other. A CFET could stack one nFET on top of a pFET sheets, or two nFETs on top of two pFET sheets. This ‘folding’ of the nFET and pFET eliminates the n-to-p separation bottleneck, reducing the cell active area footprint.
Allows independent control of nFET and pFET in the same gate line.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1A-1C illustrate an exemplary starting point of an exemplary method of making a semiconductor structure according to aspects of the invention where “A” depicts a top-down view, “B” depicts a cross-sectional view from the line “x” of FIG. 1A and “C” depicts a cross-sectional view from the line “y” of FIG. 1A;

FIGS. 2A-15C illustrate exemplary intermediate steps of an exemplary method of making a semiconductor structure according to aspects of the invention where “A” depicts a top-down view, “B” depicts a cross-sectional view from the line “x” of “A” figures and “C” depicts a cross-sectional view from the line “y” of “A” figures;

FIGS. 16A-16C illustrate an exemplary semiconductor structure according to aspects of the invention where “A” depicts a top-down view, “B” depicts a cross-sectional view from the line “x” of FIG. 16A and “C” depicts a cross-sectional view from the line “y” of FIG. 16A; and

FIG. 17 is a magnification of a portion of FIG. 16C illustrating additional exemplary features of the semiconductor structure according to aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Aspects of invention provide techniques for forming a dielectric structure which completely blocks the linking paths between a top workfunction material and a bottom work function material of a stacked transistor and for forming first contact to the top gate and a second contact to the bottom gate of a common gate line. The dielectric structure is composed of an L-shaped middle portion and plugs flanking either side of the middle portion.

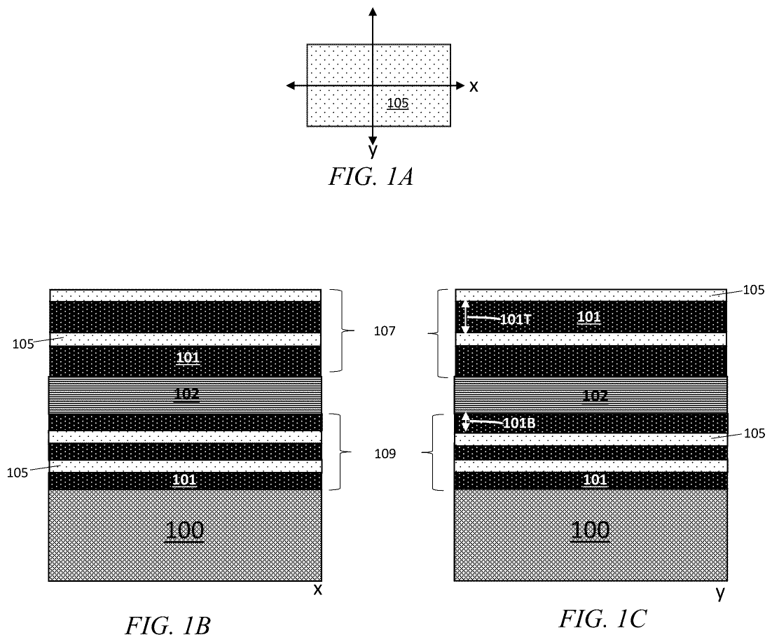

FIGS. 1A-1C depict an exemplary starting point in making the semiconductor structure in accordance with aspects of the invention. FIG. 1A is a top-down view whereas FIGS. 1B and 1C are cross-sectional views along the X axis and Y axis respectively. The semiconductor structure is built on a substrate 100 which can be any semiconductor material and is typically silicon. Alternating layers of a first sacrificial material 101 and nanosheets 105 are deposited on the substrate. A set of bottom nanosheets will become the bottom transistor 109 while a set top metal sheets will become the top transistor 107. Separating the top transistor 107 and the bottom transistor 109 is a second sacrificial material 102. The nanosheets 105 can be any semiconductor material and their typical silicon. The first sacrificial material 101 can be any material that is selectively etched relative to the nanosheet and can be low doped silicon germanium. The second sacrificial material 102 can be any material that is selectively etched relative to the nanosheets 105 and first sacrificial material 102 and can be medium doped silicon germanium. The thickness of the first sacrificial material 101 in the top transistor 107 (i.e. the “top thickness” 101T) is greater than the thickness of the first sacrificial material 101 in the bottom transistor 109 (i.e. the “bottom thickness” 101B). A larger top thickness 101T relative to the bottom thickness 101B of the sacrificial material advantageously prevents pinch-off of bottom gate materials 1200 during a later process step.

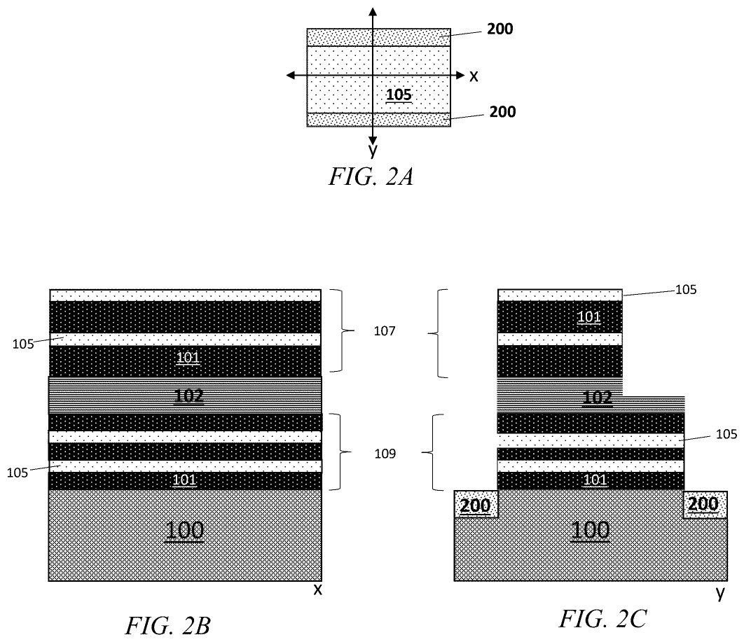

FIGS. 2A-2C depict an exemplary semiconductor structure after lithographically defining an active area and forming isolation regions 200 in accordance with aspects of the invention. FIG. 2A is a top-down view whereas FIGS. 2B and 2C are cross-sectional views along the X axis and Y axis respectively. One or more masks are used to etch portions of the nanostack and create a trench in the substrate which is filled with a dielectric material resulting in isolation regions 200 on either side of the nanostack. The shape of the remaining nanostack will be the active area of the transistor.

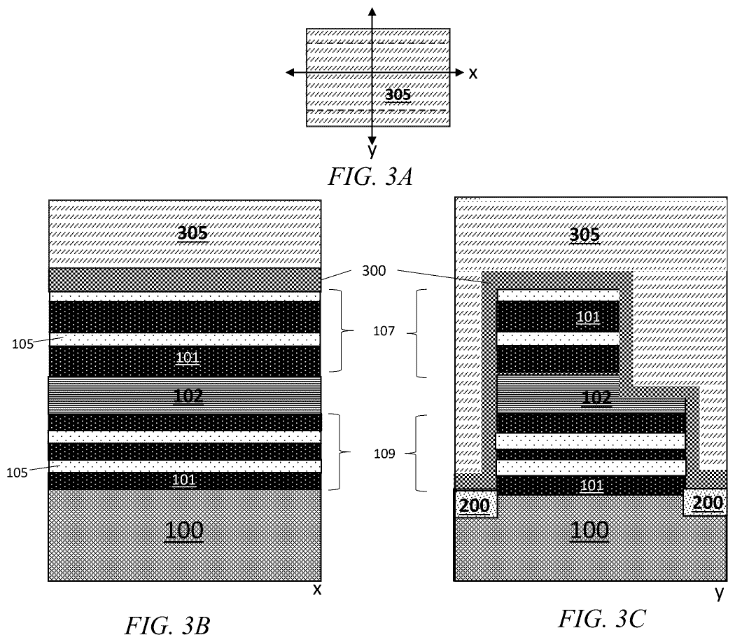

FIGS. 3A-3C depict an exemplary semiconductor structure after forming a dummy layer 300 and gate level dielectric 305 in accordance with aspects of the invention. FIG. 3A is a top-down view whereas FIGS. 3B and 3C are cross-sectional views along the X axis and Y axis respectively. The dummy layer 300 can include several layers including an oxide layer closest to the substrate and nanostack, a sacrificial amorphous silicon over the oxide layer and finally and optionally, an etch stop layer. The gate level dielectric 305 will remain in the final product at the transistor level, though not part of the transistors, therefore a lower dielectric constant material is preferred such as SiCO though silicon dioxide could also be used.

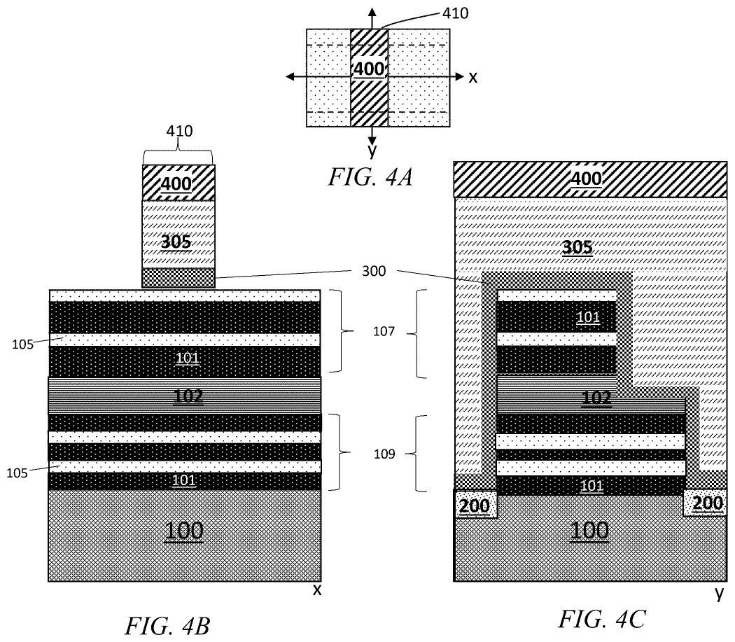

FIGS. 4A-4C depict an exemplary semiconductor structure after forming lithographically forming the gate line 410 in accordance with aspects of the invention. FIG. 4A is a top-down view whereas FIGS. 4B and 4C are cross-sectional views along the X axis and Y axis respectively. A hardmask 400 is deposited over the structure and then patterned using lithography and etching to leave a gate line 410 of the gate level dielectric and dummy layer 300 running in the y-direction and perpendicular to the active area shape (dotted lines denote where the underlying isolation regions 200 border the nanostack thereby defining the active area shape). In the gate line 410 the future channel regions and gate of the transistors will be formed.

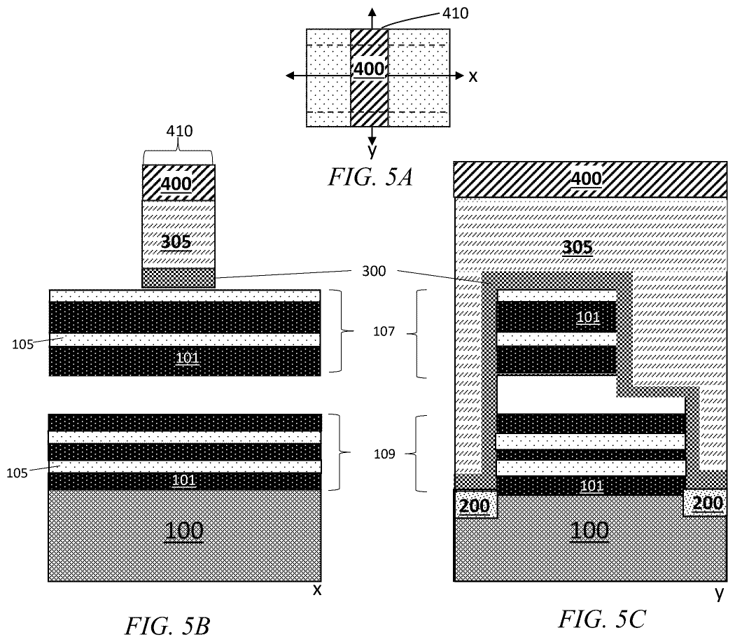

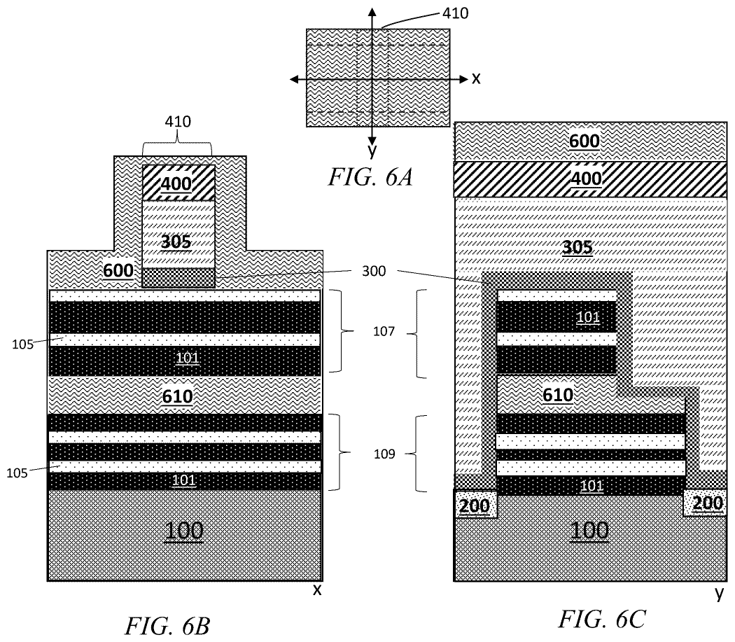

FIGS. 5A-5C depict an exemplary semiconductor structure after removing the second sacrificial material 102 layer in accordance with aspects of the invention. FIG. 5A is a top-down view whereas FIGS. 5B and 5C are cross-sectional views along the X axis and Y axis respectively. The second sacrificial material 102 layer is removed selectively relative to the first sacrificial material 101 layer using known methods. In FIGS. 6A-6C a dielectric material is deposited to cover the structure (this will be future gate spacers 600) and fill the void left in the nanostack by removing the second sacrificial material 102 (this part will be middle dielectric portion 610). The dielectric material forming the future gate spacers 600 and future middle dielectric portion 610 can be silicon nitride, silicon oxycarbon-nitride, silicon oxycarbon or other similar materials.

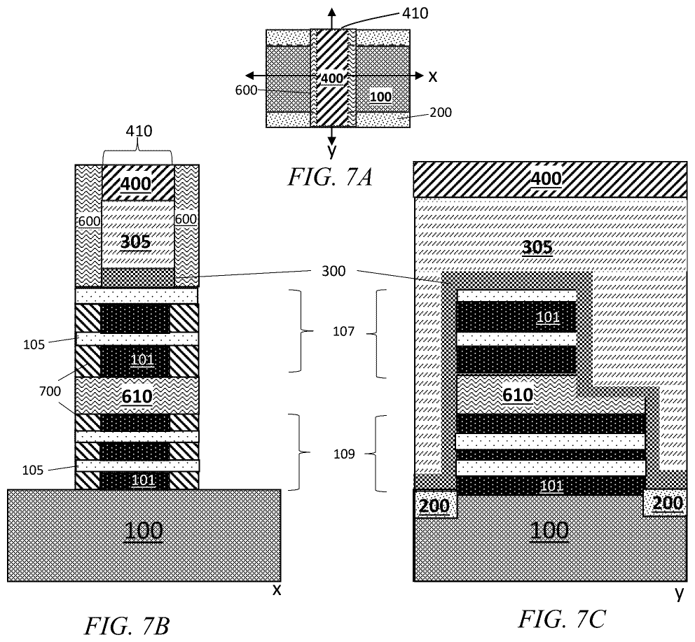

FIGS. 7A-7C depict an exemplary semiconductor structure after forming gate spacers 600 and with hardmask 400 in place, etching exposed areas of the nanostack to the substrate 100. With the edges of the nanostack exposed, the lateral portions of the first sacrificial material are recessed and a dielectric inner spacer 700 formed (See FIG. 7B). Inner spacers 700 can be nitride based dielectric films such as SiN, SiBCN, SiOCN, or can be SiOC or AlO.

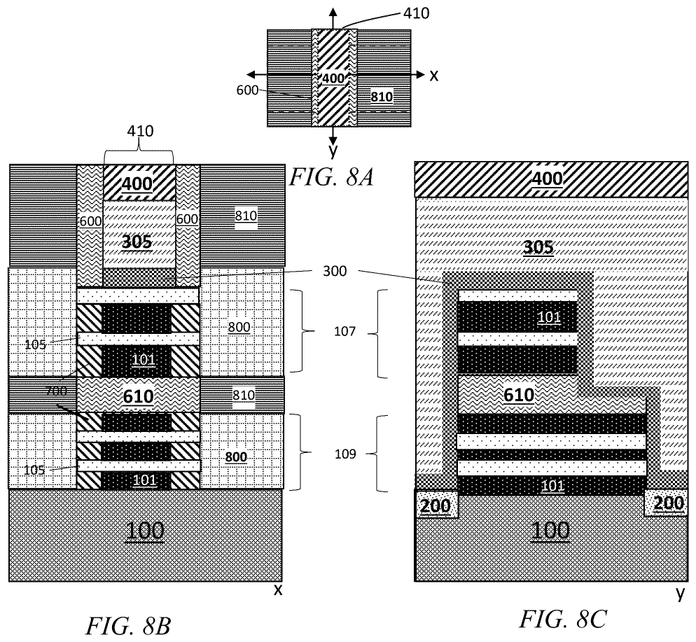

FIGS. 8A-8C depict an exemplary semiconductor structure after forming (growing) source/drains 800. Using a series of film formation processes, source/drains 800 are epitaxially grown on exposed lateral surfaces of the nanosheets 105 while a source/drain separator dielectric 810 is deposited between the growths of the bottom transistor 109 source/drains and the top transistor 107 source/drains 800. The source/drains 800 are a semiconductor material. For an n-doped transistor (nFET), silicon carbon doped with phosphorus can be used, while for a p-doped transistor pFET), silicon germanium doped with boron can be used.

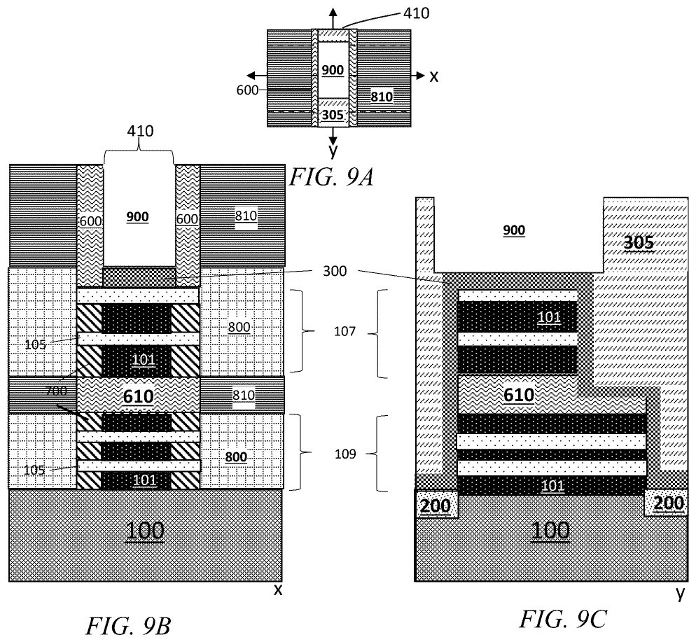

FIGS. 9A-9C depict an exemplary semiconductor structure after forming a gate line opening 900 in accordance with aspects of the invention. To achieve the structure, the hardmask 400 (FIG. 8B) is removed by polishing. Next lithography and etching are used to remove a portion of the gate level dielectric 305, the result is a gate line opening 900.

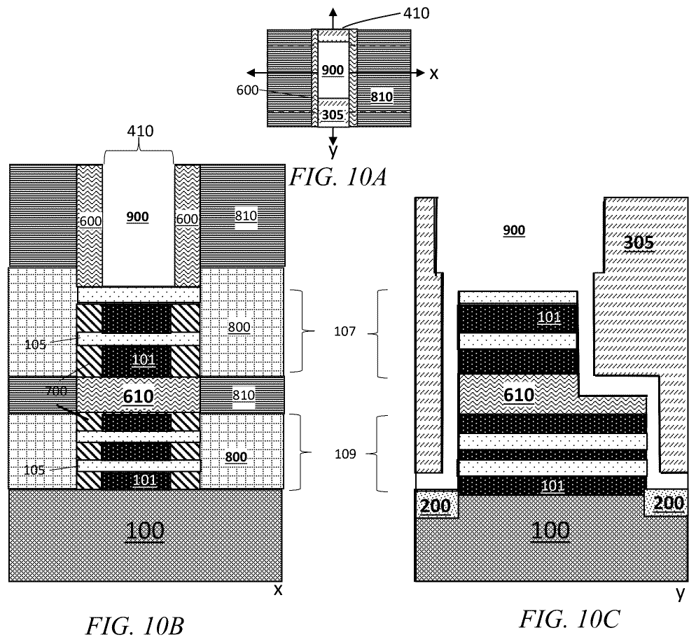

In FIGS. 10A-10C the dummy layer 300 is removed with an isotropic etch to expose the top nanosheet 105 (FIG. 10B) and to extend the gate line opening 900 around the nanosheet stack and to the substrate (FIG. 10C).

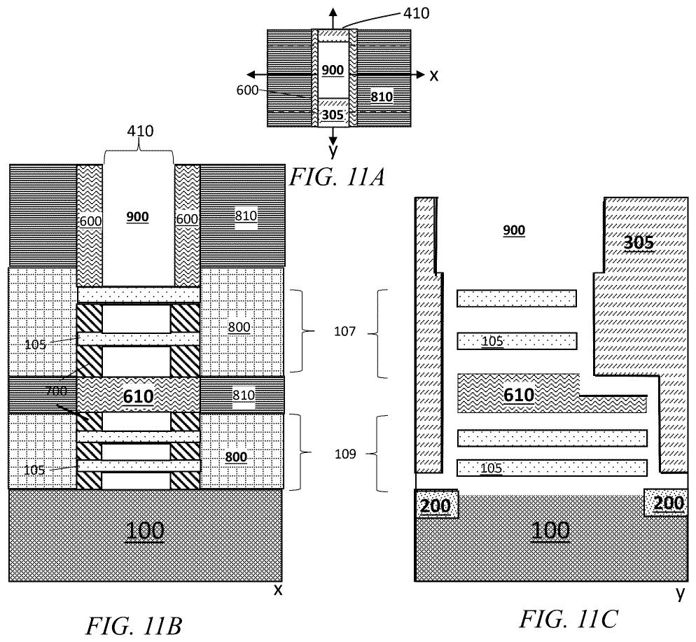

In FIGS. 11A-11C the first sacrificial material 101 layers are removed selective to the nanosheets 105. This further extends the gate line opening 900 to surround the nanosheets 105 and middle dielectric portion 610.

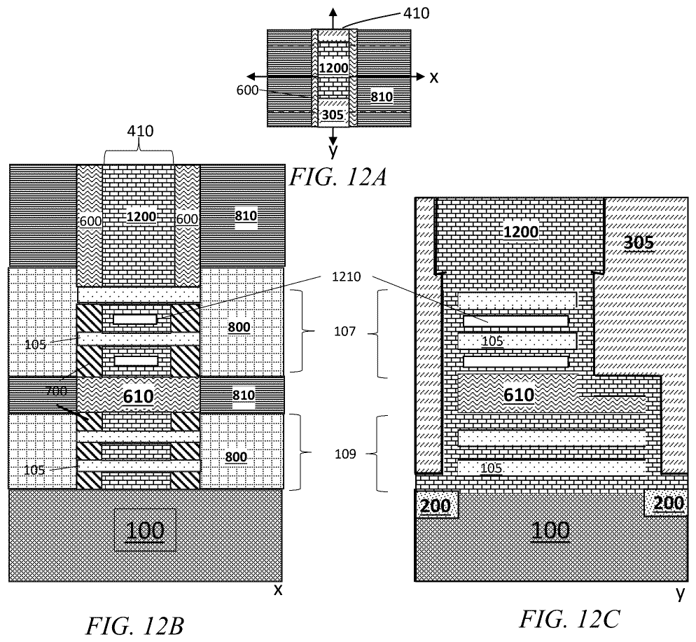

In FIGS. 12A-12C bottom gate materials 1200 are formed in the gate line opening 900. The bottom gate materials 1200 include bottom gate oxide and bottom work function material. The bottom gate oxide wraps around the nanosheets 105. Between the bottom gate oxide and the nanosheets 105 there can be an interfacial layer on the nanosheets 105. The bottom work function material is on the bottom gate oxide around the nanosheets 105 and contacts the gate level dielectric 305 on the sidewalls of the gate line opening 900. The interfacial layer can be silicon oxide or silicon oxynitride. The bottom gate oxide can by a high-k dielectric material, where high-k means dielectric constant greater than 4 and advantageously greater than 7, for example, a hafnium oxide, a hafnium aluminum oxide, a hafnium lanthanum oxide, a hafnium silicon oxide, a hafnium zirconium oxide, or a zirconium oxide. Bottom work function material 1200 can be one or more of a metal nitride (e.g. TiN, WN), or titanium or aluminum, or an alloy containing Ti or Al (e.g. TiAlC, TiAl, Ti, Al, etc.). Because the spacing between the nanosheets 105 in the top transistor 107 is larger, a void 1210 in the bottom workfunction material can appear in the top transistor 107.

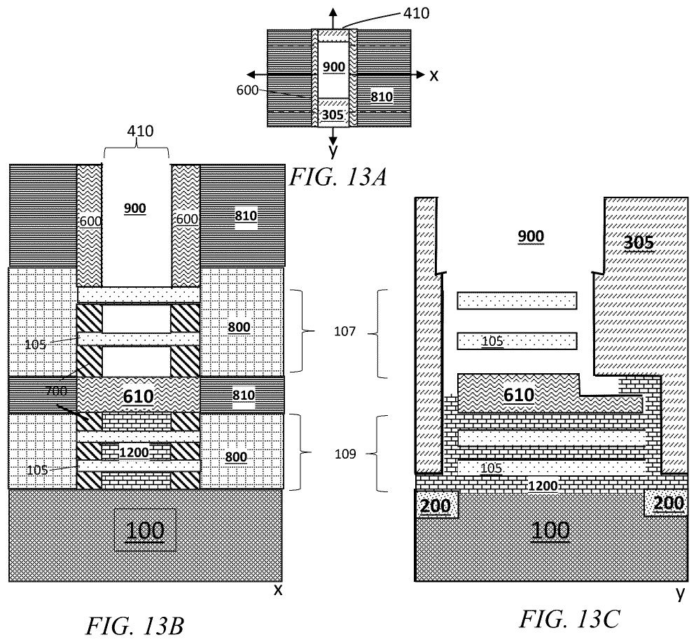

In FIGS. 13A-13C bottom gate materials 1200 are conformally etched back from the top transistor 107 to expose the top nanosheets 105 and a portion of the L-shaped middle dielectric portion 610. The etch process can be isotropic by either a dry or a wet method; for example, SC1.

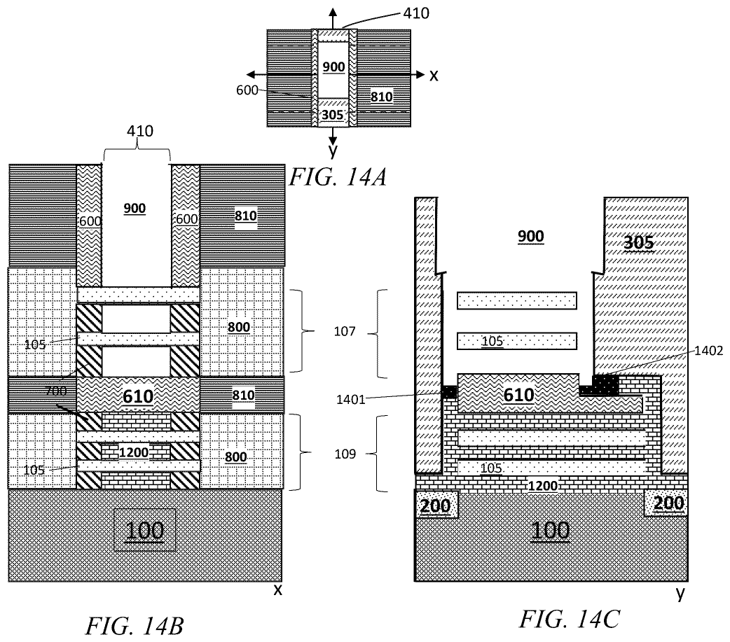

In FIGS. 14A-14C a dielectric material is formed in the recesses of the top transistor and then etched back to leave a dielectric plug laterally bordering the middle dielectric portion 610. Referring to FIG. 14C, when viewed in cross-section the dielectric plug appears as a first plug 1401 and a second plug 1402 one on either side of the middle dielectric portion 610. The first plug 1401 and the second plug can be a nitride and/or oxide based dielectric film formed by atomic layer deposition. The etch back process can be isotropic by either a dry or a wet method; for example, HF.

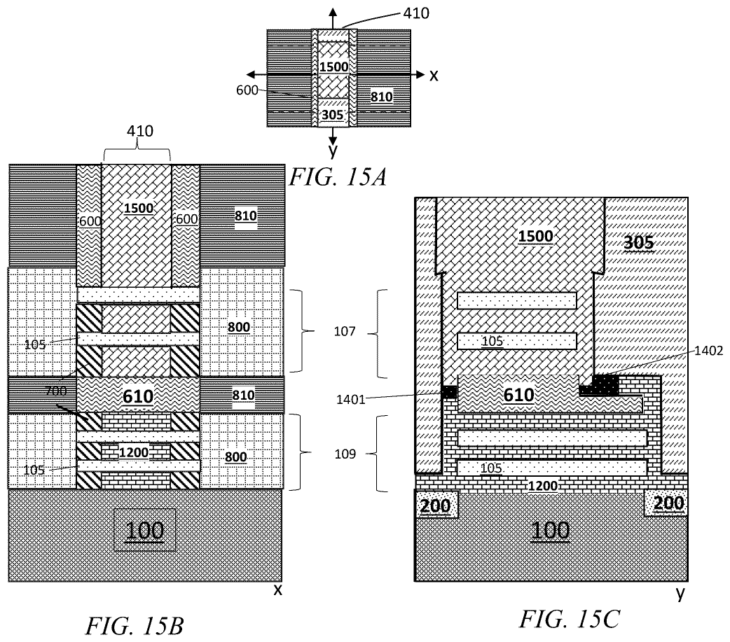

In FIGS. 15A-15C top gate materials 1500 are formed in the gate line opening 900. The top gate materials 1500 include top gate oxide and top work function material. The top gate oxide wraps around the nanosheets 105 in the top transistor 107. Between the top gate oxide and the nanosheets 105 there can be an interfacial layer on the nanosheets 105. The top work function material is on the top gate oxide around the nanosheets 105 and contacts the gate level dielectric 305 on the sidewalls of the gate line opening 900. The interfacial layer can be silicon oxide or silicon oxynitride. The bottom gate oxide can by a high-k dielectric material, where high-k means dielectric constant greater than 4 and advantageously greater than 7, for example, a hafnium oxide, a hafnium aluminum oxide, a hafnium lanthanum oxide, a hafnium silicon oxide, a hafnium zirconium oxide, or a zirconium oxide. The top gate oxide can have substantially the same thickness as the bottom gate oxide. The top work function material can be one or more of a metal nitride (e.g. TiN, WN), or titanium or aluminum, or an alloy containing Ti or Al (e.g. TiAlC, TiAl, Ti, Al, etc.). The top workfunction material can have the same or different selection of layers than the bottom workfunction material. The top workfunction material can have the same or different thickness as the bottom workfunction material.

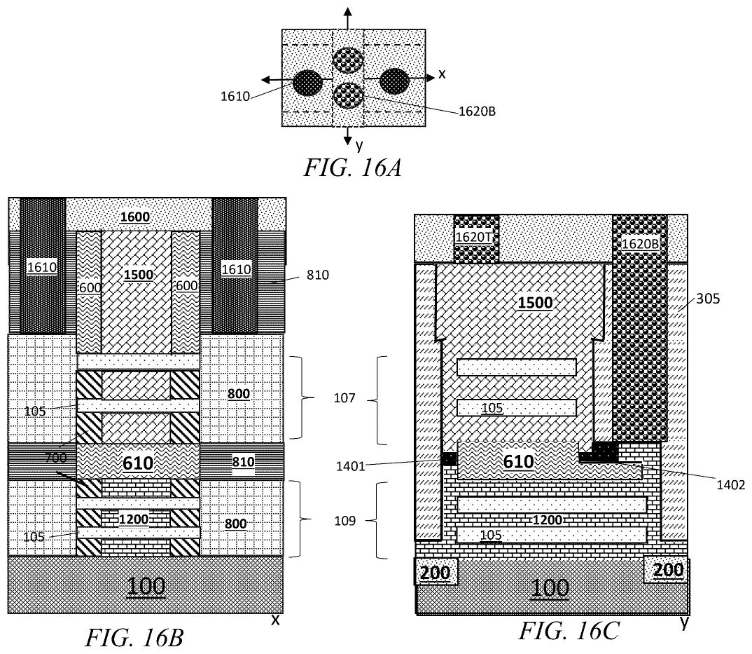

In FIGS. 16A-16C, the contacts are formed to the source/drains 800 and gate of the top transistor 107 and the bottom transistor 109 to form the semiconductor structure. One skilled in the art will recognize back end of line layers will be added to the structure to wire the transistors into circuits. The contacts are formed through a contact level dielectric 1600 which can be one or more layers of dielectric materials including silicon nitride, silicon oxide, silicon oxycarbon, silicon oxycarbon nitride, for example, or other similar materials. The source/drain contacts 1610 and the gate contacts 1620 can include one or more layers of conducting materials including titanium, titanium nitride, tungsten, ruthenium, or cobalt, for example, or other similar materials. The semiconductor structure of claim 1 further comprising a top gate contact 1620T to the top transistor 107 and a bottom gate contact 1620B to the bottom transistor 109. Referring to FIG. 16C, the top gate contact 1620T is shorter than the bottom gate contact 1620B but is still has a top surface co-planar with the bottom gate contact 1620B.

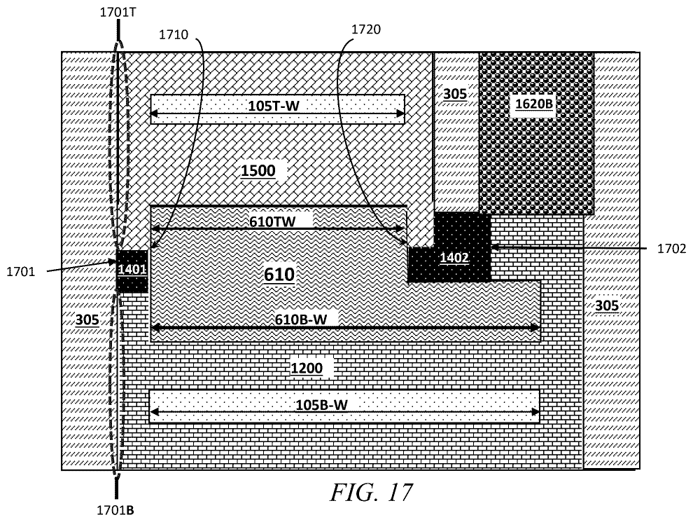

FIG. 17 is a magnification of dielectric structure separating the bottom transistor 109 and its set of nanosheets 105B and the top transistor and its set of nanosheets 105T of FIG. 16C. The dielectric structure includes several parts, namely the middle dielectric portion 610, the first plug 1401 laterally contacting a first side 1710 of the middle dielectric portion and the second plug 1402 laterally contacting a second side 1720 of the middle dielectric portion 610. The middle dielectric portion 610 has a “stepped” or “L-shape”. Because of the L-shape of the middle dielectric portion 610, it has a top width 610TW and a bottom width 610B-W, with the bottom width 610B-W being greater than the top width 610TW. The top width 610TW is approximately the same width within process tolerances as the top sheet width 105T-W. The bottom width 610B-W is approximately the same width within process tolerances as the bottom sheet width 105B-W. It follows, therefore, that the top set of nanosheets 105T have a top sheet width 105T-W less than the bottom sheet width 105B-W of the bottom set of nanosheets 105B.

Still referring to FIG. 17, the first plug 1401 is vertically in contact with the top workfunction material (part of top gate material 1500) and the bottom workfunction material (part of bottom gate material 1200). The first plug 1401 has a first sidewall 1701 that is vertically aligned with a top workfunction material sidewall 1701T and a bottom workfunction material sidewall 1701B. The second plug 1402 is vertically in contact with the top workfunction material (part of top gate material 1500) and the middle dielectric portion 610. The second plug 1402 has a plug sidewall 1702 that contacts the bottom workfunction material (part of bottom gate material 1200). The plug sidewall 1702 is an outer sidewall of the plug relative to the middle dielectric portion 610. Like the middle dielectric portion 610, the second plug 1402 is also, “stepped” but to make backwards “L”. Therefore, the second plug 1402 also has two widths and heights, similar to middle dielectric portion 610. Note that neither the first plug 1401 nor the second plug 1402 are completely bordered by workfunction material or middle dielectric portion 610, instead each has at least a portion of a side in contact with embedded in gate level dielectric 305.

In summary, aspects of the invention include a semiconductor structure including a gate line 410 having a gate line opening 900, a pair of source/drains 800 on either side of the gate line 410, a bottom transistor 109 in the gate line opening 900. The bottom transistor 109 includes a bottom set of nanosheets 105 wrapped by a bottom workfunction material (part of bottom gate material 1200). The semiconductor structure further includes a top transistor 107 over the bottom transistor 109 in the gate line opening 900, the top transistor comprising a top set of nanosheets 105T wrapped by a top workfunction material (part of top gate material 1500). A dielectric structure separates the bottom transistor and the top transistor. The dielectric structure includes an L-shaped middle dielectric portion 610, a first plug 1401 laterally contacting a first side 1710 of the L-shaped middle dielectric portion and a second plug 1402 laterally contacting a second side 1720 of the L-shaped middle dielectric portion 610.

In addition, the first plug 1401, in a vertical direction, is in contact with the top workfunction material (part of top gate material 1500) and the bottom workfunction material (part of bottom gate material 1200). Furthermore, the first plug 1401 has a first sidewall 1701 that is vertically aligned with a top workfunction material sidewall 1701T and a bottom workfunction material sidewall 1701B.

Moving to the second plug 1402, it is vertically in contact with the top workfunction material (part of top gate material 1500) and the L-shaped middle dielectric portion 610. Furthermore, the semiconductor structure of claim 1 wherein the second plug 1402 has a plug sidewall 1702 that contacts the bottom workfunction material (part of bottom gate material 1200). The second plug 1402 can have a stepped profile.

The semiconductor structure can further include a top gate contact 1620T to the top transistor 107 and a bottom gate contact 1620B to the bottom transistor 109. The top gate contact 1620T can be shorter than the bottom gate contact 1620B. In addition, the top gate contact 1620T can be co-planar with the bottom gate contact 1620B.

Furthermore, the top set of nanosheets 105T has a top sheet width 105T-W and the bottom set of nanosheets has a bottom sheet width 105B-W. The top sheet width 105T-W can be less than the bottom sheet width 105B-W.

In addition, the L-shaped middle dielectric portion 610 has top width 610T-W and a bottom width 610B-W in which the top width 610T-W is less than the bottom width 610B-W. In addition, the top width 610T-W and the top sheet width 105T-W are the same within process tolerances (or in a non-limiting example, within 10% of each other). While the bottom width 610B-W and the bottom sheet width 105B-W area also the same within process tolerances (or in a non-limiting example, within 10% of each other).

In another aspect of the invention, a stacked complementary field effect transistor (CFET) includes a top set of nanosheets 105T surrounded by a top workfunction material (part of top gate material 1500), a bottom set of nanosheets 105B surrounded by a bottom workfunction material (part of bottom gate material 1200) in which the top set of nanosheets 105T is over the bottom set of nanosheets 105B. The CFET also includes a dielectric structure separating the top set of nanosheets 105T from the bottom set of nanosheets 105B in which the dielectric structure comprises a stepped middle dielectric portion 610 laterally flanked by a first plug 1401 on a first side, and a stepped second plug 1402 on a second side 1720. In some cases, a top nanosheet width 105T-W can be less than a bottom nanosheet width 105B-W. In addition, a gate level dielectric 305 can be on either side of the top set of nanosheets 105T and the bottom set of nanosheets 105B.

In some instances, the first plug 1401 is in contact with the stepped middle dielectric portion 610, the top workfunction material (part of top gate material 1500), the bottom workfunction material (part of bottom gate material 1200) and the gate level dielectric 305; while the stepped second plug 1402 is in contact with the stepped middle dielectric portion 610, the top workfunction material, the bottom workfunction material and the gate level dielectric 305. The first plug 1401 can be laterally in contact with the stepped middle dielectric portion 610, vertically in contact with the top workfunction material, vertically in contact with the bottom workfunction material and laterally in contact with the gate level dielectric 305. The stepped second plug 1402 can be laterally in contact with the stepped middle dielectric portion 610, vertically in contact with the top workfunction material, laterally in contact with the bottom workfunction material and vertically in contact with the gate level dielectric 305.

In yet a further aspect of the invention, a method of forming a semiconductor structure includes forming an alternating stack of nanosheets 105 and sacrificial material on a substrate 100, the alternating stack having a top stack (which will become top transistor 107), a bottom stack (which will become bottom transistor 109) and a middle sacrificial layer 102 vertically between the top stack and the bottom stack and then patterning the alternating stack to form an active area having a stepped profile flanked by isolation regions 200, thereby forming a patterned alternating stack. A dummy layer 300 and a gate level dielectric 305 are formed on the substrate and patterned to from a gate line 410. Next the middle sacrificial layer is replaced from the patterned alternating stack with a middle dielectric portion 610 and the patterned alternating stack on either side of the gate line 410 is etched to expose sidewalls of the nanosheets 105 and the sacrificial material. The exposed sidewalls of the sacrificial material are etched to form recesses in which inner spacers 700 are placed. From the exposed sidewalls of the nanosheets source/drains are grown. Next an opening over the gate line (gate line opening 900) is made to expose the dummy layer which is subsequently removed to expose a top and sidewalls of the patterned alternating stack in the gate line 410. This allows removal of the sacrificial material from the patterned alternating stack. Now a bottom gate material 1200 can be formed around the nanosheets 105 and middle dielectric portion 610 in the gate line 410. The bottom gate material 1200 is recessed to expose the top stack 107 and a part of the middle dielectric portion 610. A first plug 1401 and a second plug 1402 are formed on either side of the middle dielectric portion 610. A top gate material 1500 is formed on the first plug 1401, the second plug 1402, the middle dielectric portion 610 and the top stack.

Bulk silicon is a non-limiting example of a suitable substrate material, other materials are also possible.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for case of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a gate line having a gate line opening;
a pair of source/drains on either side of the gate line;
a bottom transistor in the gate line opening, the bottom transistor comprising a bottom set of nanosheets wrapped by a bottom workfunction material;
a top transistor over the bottom transistor in the gate line opening, the top transistor comprising a top set of nanosheets wrapped by a top workfunction material; and
a dielectric structure separating the bottom transistor and the top transistor wherein the dielectric structure comprises a middle dielectric portion, a first plug laterally contacting a first side of the middle dielectric portion and a second plug laterally contacting a second side of the middle dielectric portion;
wherein the middle dielectric portion is L-shaped.

2. The semiconductor structure of claim 1 wherein the first plug is vertically in contact with the top workfunction material and the bottom workfunction material.

3. The semiconductor structure of claim 1 wherein the first plug has a first sidewall that is vertically aligned with a top workfunction material sidewall and a bottom workfunction material sidewall.

4. The semiconductor structure of claim 1 wherein the second plug is vertically in contact with the top workfunction material and the middle dielectric portion.

5. The semiconductor structure of claim 1 wherein the second plug has a plug sidewall that contacts the bottom workfunction material.

6. The semiconductor structure of claim 1 wherein the second plug is stepped.

7. The semiconductor structure of claim 1 further comprising a top gate contact to the top transistor 107 and a bottom gate contact to the bottom transistor.

8. The semiconductor structure of claim 7 wherein the top gate contact is shorter than the bottom gate contact.

9. The semiconductor structure of claim 8 wherein in the top gate contact is co-planar with the bottom gate contact.

10. The semiconductor structure of claim 1 wherein the top set of nanosheets has a top sheet width and the bottom set of nanosheets has a bottom sheet width; and
wherein the top sheet width the is less than the bottom sheet width.

11. The semiconductor structure of claim 10 wherein the middle dielectric portion has top width and a bottom width; and
wherein top width is less than the bottom width.

12. The semiconductor structure of claim 11 wherein the top width and the top sheet width are the same within process tolerances.

13. The semiconductor structure of claim 12 wherein the bottom width and the bottom sheet width are the same within process tolerances.

14. A stacked complementary field effect transistor comprising:
a top set of nanosheets surrounded by a top workfunction material;
a bottom set of nanosheets surrounded by a bottom workfunction material, wherein the top set of nanosheets is over the bottom set of nanosheets; and
a dielectric structure separating the top set of nanosheets from the bottom set of nanosheets;
wherein the dielectric structure comprises a stepped middle dielectric portion laterally flanked by a first plug on a first side, and a stepped second plug on a second side.

15. The stacked complementary field effect transistor of claim 14 further comprising:
a top nanosheet width; and
a bottom nanosheet width;
the top nanosheet width is less than the bottom nanosheet width.

16. The stacked complementary field effect transistor of claim 14 further comprising:
a gate level dielectric 305 on either side of the top set of nanosheets and the bottom set of nanosheets.

17. The stacked complementary field effect transistor of claim 16,
wherein the first plug is in contact with the stepped middle dielectric portion, the top workfunction material, the bottom workfunction material and the gate level dielectric; and
wherein the stepped second plug is in contact with the stepped middle dielectric portion, the top workfunction material, the bottom workfunction material and the gate level dielectric.

18. The stacked complementary field effect transistor of claim 17,
wherein the first plug is laterally in contact with the stepped middle dielectric portion, vertically in contact with the top workfunction material, vertically in contact with the bottom workfunction material and laterally in contact with the gate level dielectric.

19. The stacked complementary field effect transistor of claim 17,
wherein the stepped second plug is laterally in contact with the stepped middle dielectric portion, vertically in contact with the top workfunction material, laterally in contact with the bottom workfunction material and vertically in contact with the gate level dielectric.

20. A method of forming a semiconductor structure, comprising:
forming an alternating stack of nanosheets and sacrificial material on a substrate, the alternating stack having a top stack, a bottom stack and a middle sacrificial layer vertically between the top stack and the bottom stack;
patterning the alternating stack to form an active area having a stepped profile flanked by isolation regions, thereby forming a patterned alternating stack;
forming a dummy layer and a gate level dielectric of the substrate;
patterning the dummy layer and the gate level dielectric to form a gate line;
replacing the middle sacrificial material layer from the patterned alternating stack with a middle dielectric portion;
etching the patterned alternating stack on either side of the gate line to expose sidewalls of the nanosheets and the sacrificial material;
etching exposed sidewalls of the sacrificial material to form recesses;
forming inner spacers in the recesses;
growing source/drains from the exposed sidewalls of the nanosheets;
forming an opening over the gate line to expose the dummy layer;
removing the dummy layer to expose a top and sidewalls of the patterned alternating stack in the gate line;
removing the sacrificial material from the patterned alternating stack;
forming a bottom gate material around the nanosheets and the middle dielectric portion in the gate line;
recessing the bottom gate material to expose the top stack and a part of the middle dielectric portion;
forming a first plug and a second plug on either side of the middle dielectric portion; and
forming a top gate material on the first plug, the second plug, the middle dielectric portion and the top stack.
